(19) United States
(12) Patent Application Publication
(10) Pub. No.: US 2007/0195580 A1
(43) Pub. Date: Aug. 23, 2007

(54) Memory circuit having a resistive memory cell and method for operating such a memory circuit

(76) Inventors: Heinz Hoenigschmid, Poecking (DE); Corvin Liaw, Munich (DE); Milena Dimitrova, Munich (DE); Michael Angerbauer, Munich (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/361,062

(22) Filed: Feb. 23, 2006

(51) Int. Cl. G11C 11/00; G11C 7/00

(52) U.S. Cl. 365/148; 365/203

(57) ABSTRACT

The invention relates to a memory circuit comprising a resistive memory cell having a selection transistor and a resistive memory element connected in series, wherein the resistive memory element is coupled to a plate potential; and a control circuit to control the selection transistor by means of an activation signal a pre-charge circuit coupled with a node between the selection transistor and the resistive memory element and to apply a compensation potential to the node; wherein the control circuit controls the pre-charge circuit so that a compensation potential is applied to the node prior to a level transition of the activation signal.

### BACKGROUND OF THE INVENTION

1. Field of the Invention

The present invention relates to a memory circuit having a resistive memory cell and a method for operating such a memory circuit.

2. Description of the Related Art

Resistive memory cells comprise a resistive memory element which is capable of storing an information as a resistance state, i.e., the resistive memory element can acquire different resistances. One example for such a resistive memory element is a Conductive Bridging Random Access Memory (CBRAM) element, also called a Programmable Metallization Cell (PMC) memory element. Such resistive memory elements have a dielectric material, e.g., a chalcogenide material, which is a solid state electrolyte in which a conductive path can be selectively established when movable ions migrate from an electrode into the dielectric material and degenerated when the ions are removed therefrom. A change of the resistance state of such a resistive memory element can be carried out by applying an electrical field. Programming, i.e., bringing the resistive memory element into a low resistance state, can be performed by applying a programming voltage which is higher than a programming threshold voltage. Erasing of the resistive memory element, i.e., bringing the resistive memory element into a high resistance state, can be performed by applying an erasing voltage which is lower than an erasing threshold voltage wherein, usually, the programming voltage and the erasing voltage are inverse in sign.

To form a resistive memory cell, the resistive memory element can be coupled in series with a selection transistor. The resistive memory cell is connected with a plate element by one terminal for applying a plate potential and connected with a bit line by another terminal. At a node between the selection transistor and the resistive memory element, a disturbance may be induced which may result in the resistance state of the resistive memory element being slightly changed. Therefore, repeated disturbances can lead to a change of the data stored in the resistive memory element. Thus, the data retention time essentially depends on the number of read cycles after writing a data into the respective resistive memory cell. Even if the data can be correctly read out the resistive memory cell, the change of the resistance of the resistive memory element can lead to a prolongation of the access time to the resistive memory cell.

Disturbances can be a result of level transitions of an activation signal on a word line which are used to control the selection transistor. The disturbances may result in a voltage pulse being added to the potential of the node so that the programming threshold voltage of the resistive memory element is exceeded.

### SUMMARY OF THE INVENTION

One aspect of the invention reduces the degradation of the resistance state of the resistive memory element in a memory cell so that the retention time of the data stored in the resistive memory cell can be prolonged.

According to a first embodiment of the present invention, a memory circuit is provided which comprises a resistive memory cell having a selection transistor and a resistive memory element connected in series, wherein the resistive memory element is coupled with a plate potential, a control circuit to control the selection transistor by means of an activation signal and a pre-charge circuit coupled with a node between the selection transistor and the resistive memory element and to apply a compensation potential to the node, wherein the control circuit controls the pre-charge circuit so that a compensation potential is applied to the node prior to a level transition on the activation signal.

The appliance of the compensation potential on the node allows for selection of the voltage level of the node on which an induced voltage peak resulting from a cross-coupling of the level transition of the activation signal is added. Thereby, it can be achieved that the compensation potential and the potential resulting from the voltage peak are both located below the programming threshold voltage of the resistive memory element.

According to another embodiment of the present invention, the resistive memory element acquires a high resistance state by applying an erasing voltage which is lower (e.g., more negative) than an erasing threshold voltage, and acquires a low resistance state by applying a programming voltage which is higher (e.g., more positive) than a programming threshold voltage, the programming voltage and the erasing voltage having an inverse polarity.

Furthermore, the control circuit may activate the pre-charge circuit only if the resistive memory element is in its high resistance state. The cross-talk of the level transition of the activation signal has a minor effect if the node is coupled with the plate potential by means of a low resistance of the resistive memory element. Therefore, it is particularly necessary to use the pre-charge circuit if the node is coupled with the plate potential with a high resistance.

Moreover, the compensation potential may be selected so that a coupling signal induced by the level transition of the activation signal at the node is at least partially compensated. The compensation potential may be further selected so that the voltage over the resistive memory element is below the programming threshold voltage.

The control circuit can control the pre-charge circuit to apply the compensation voltage after a closing of the selection transistor.

According to another embodiment of the present invention, a memory circuit is provided which comprises a resistive memory cell having a selection transistor and a resistive memory element connected in series, wherein a plate potential is connected with a first terminal of the resistive memory cell, a bit line coupled with a second terminal of the resistive memory cell, a control circuit to control the selection transistor and a pre-charge circuit to supply a compensation potential on the bit line prior to an opening rendering the selection transistor non-conductive.

Furthermore, the control circuit can control the pre-charge circuit to apply the compensation potential after closing the selection transistor.

Moreover, the resistive memory element may acquire a high resistance state by applying an erasing voltage which is lower than an erasing threshold voltage and acquire a low resistance state by applying a programming voltage which is higher than a programming threshold voltage.

The control circuit may apply an activation signal on a word line to selectively open and close the selection transistor, wherein the compensation potential is selected so that a coupling signal induced by a level transition of the activation signal at a node between the selection transistor and the resistive memory element is at least partially compensated.

The applied compensation potential may be further selected so that the resulting voltage over the resistive memory element is within a range between the programming threshold voltage and the erasing threshold voltage.

According to another embodiment of the present invention, a memory access circuit is provided for at least one of writing a data to or reading a data from the resistive memory cell, wherein the control circuit further controls the pre-charge circuit to apply the compensation potential depending on the resistance state of the resistive memory element related to the data written to or read from the resistive memory cell.

According to another embodiment of the present invention, a memory circuit is provided which comprises a resistive memory cell having a selection transistor and a resistive memory element connected in series, wherein a plate potential is coupled with a first terminal of the resistive memory cell, a bit line coupled with a second terminal of the resistive memory cell, a control circuit to control the selection transistor and a pre-charge circuit to supply a compensation current to the resistive memory cell via the bit line, wherein the control circuit further controls the pre-charge circuit to apply the compensation current via the bit line through the resistive memory cell prior to an opening of the selection transistor.

Furthermore, the resistive memory element may acquire a high resistance state by applying an erasing voltage which is lower than an erasing threshold voltage and acquire a low resistance state by applying a programming voltage which is higher than a programming threshold voltage.

Moreover, the resistive memory element acquires a high resistance state by applying an erasing voltage which is lower than an erasing threshold voltage and to acquire a low resistance state by applying a programming voltage which is higher than a programming threshold voltage.

According to another embodiment of the present invention, the compensation current is applied to the resistive memory cell for a predetermined time so that it results in a compensation potential applied to a node between the selection transistor and the resistive memory element if the resistive memory element is in the high resistance state, and so that it results in a further potential applied to the node if the resistive memory element is in the low resistance state wherein the further potential is selected so that a voltage applied to the resistive memory element is higher than the erasing threshold voltage.

According to another embodiment of the present invention, a memory circuit is provided which comprises a resistive memory cell having a selection transistor and a resistive memory element connected in series, wherein a plate potential is connected to a first terminal of the resistive memory cell, a bit line coupled with a second terminal of the resistive memory cell, a control circuit to control the selection transistor and a pre-charge/writing circuit to supply one of a compensation current and a writing current to the resistive memory cell via the bit line, wherein the control circuit further controls the pre-charge/writing circuit to apply the compensation current via the bit line through the resistive memory cell prior to an opening of the selection transistor or to apply the writing current via the bit line through the resistive memory cell to bring the resistive memory element of the resistive memory cell into a defined resistance state.

Moreover, the compensation current may be applied to the resistive memory cell for a predetermined time so that it results in a compensation potential applied on a node between the selection transistor and the resistive memory element if the resistive memory element is in the high resistance state and so that it results in a further potential applied to the node if the resistive memory element is in the low resistance state wherein the further potential is selected such that a voltage applied to the resistive memory element is higher than the erasing threshold voltage.

Furthermore, the writing current may be selected so that it results in a potential applied to a node between the selection transistor and the resistive memory element which selectively brings the resistive memory element in either the high or the low resistance state.

According to another embodiment of the present invention, a method for operating a memory circuit comprising a resistive memory cell having a selection transistor and a resistive memory element connected in series is provided. The method includes the steps of controlling the selection transistor by means of an activation signal and of applying a compensation potential to a node between the selection transistor and the resistive memory element prior to a level transition of the activation signal.

It may be provided that the compensation potential is applied only if the resistive memory element is in its high resistance state.

Moreover, the compensation potential may be selected so that a coupling signal induced by the level transition of the activation signal at the node is at least partially compensated, wherein the compensation potential is further selected so that the voltage over the resistive memory element is below the programming threshold voltage so that no programming of the resistive memory element occurs.

According to another embodiment of the present invention, a method for operating a resistive memory cell comprising a selection transistor and a resistive memory element connected in series is provided, wherein the resistive memory cell is coupled to a bit line. The method comprises the steps of controlling the selection transistor by means of an activation signal and of applying a compensation potential on the bit line prior to applying the activation signal which opens the selection transistor.

According to another embodiment of the present invention, the activation signal is supplied on a word line to open and to close, selectively, the selection transistor wherein the compensation potential is selected so that a coupling signal induced by a level transition of the activation signal at a node between the selection transistor and the resistive memory element is at least partially compensated.

Moreover, the compensation potential is further selected so that the resulting voltage applied to the resistive memory element is below the programming threshold voltage so that no programming of the resistive memory element occurs.

Furthermore, the method may further include writing a data to or reading a data from the resistive memory cell and further, applying the compensation potential depending on the resistance state of the resistive memory element related to the data written to or read from the resistive memory cell.

According to another embodiment of the present invention, a method for operating a resistive memory cell is provided which comprises a selection transistor and a resistive memory element connected in series. The method includes the steps of controlling the selection transistor by means of an activation signal and of applying a compensation current via the bit line through the resistive memory cell prior to an opening of the selection transistor wherein the programming current is applied for a predetermined time, wherein the resulting voltage applied to the resistive memory element is below a programming threshold voltage so that no programming of the resistive memory element occurs.

Furthermore, the predetermined time and the compensation current may be selected in such a way that it results in a compensation potential applied on a node between the selection transistor and the resistive memory element if the resistive memory element is in the high resistive state and such that it results in a further potential applied on the node if the resistive memory element is in the low resistance state, wherein the further potential is selected so that a voltage applied on the resistive memory element is higher than an erasing threshold voltage over which no erasing of the resistive memory element occurs.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic cross-sectional view of a resistive memory element which is used in the present invention;

FIG. 2 shows a current voltage characteristic for the resistive memory element shown in FIG. 1;

FIG. 3 shows a portion of a memory circuit with a memory cell according to the prior art;

FIG. 4 shows a small signal diagram of the memory cell of FIG. 3;

FIG. 5 shows a signal-time-diagram of the activation signal and the resulting node potential at the node N;

FIG. 6 shows a timing diagram showing the timing of the node potential according to one aspect of the present invention;

FIG. 7 shows a schematic diagram of a memory circuit according to the first embodiment of the present invention;

FIG. 8 shows a schematic diagram of a memory circuit according to a further embodiment of the present invention;

FIG. 9 shows a schematic diagram of a memory circuit according to a further embodiment of the present invention;

FIG. 10 shows a schematic diagram of a memory circuit according to a further embodiment of the present invention;

FIG. 11 shows a schematic diagram of a memory circuit according to a further embodiment of the present invention wherein the polarity of the resistive memory element is reversed.

### DETAILED DESCRIPTION OF THE PREFERRED EMBODIMENT

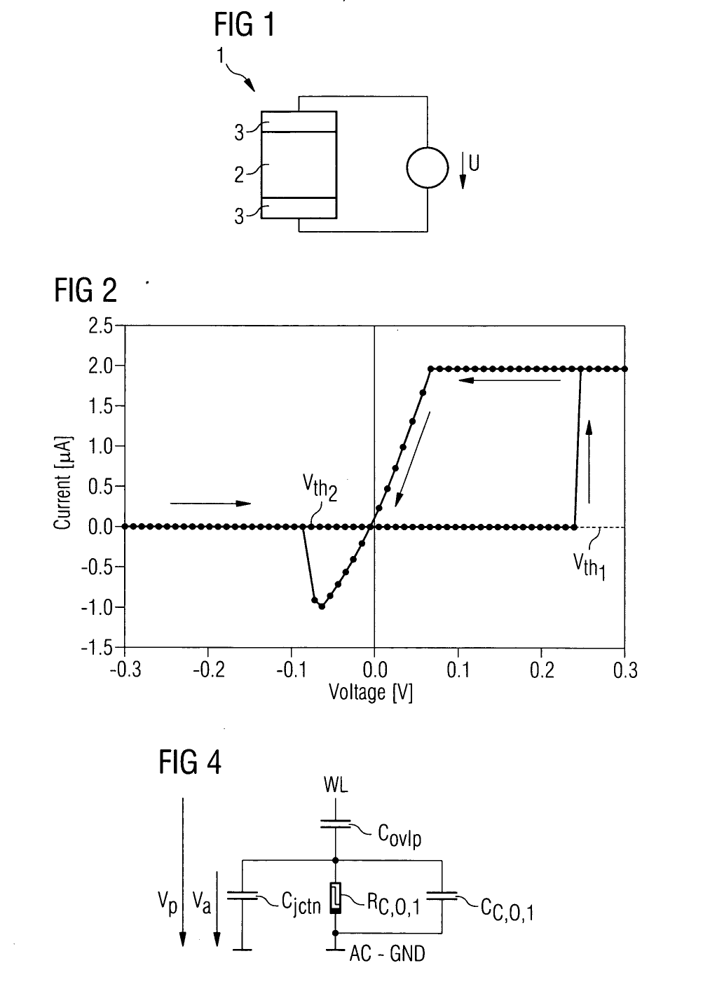

FIG. 1 depicts a cross-sectional schematic view of a resistive memory element 1 as preferably used in the present invention. The resistive memory element 1 comprises a dielectric solid state electrolyte region 2 which is arranged between two electrodes 3, an anode and cathode, wherein the anode comprises a conductive material such as Ag, the ions of which can migrate into the material of the dielectric region 2 if a positive electrical field is applied between the anode and the cathode. The cathode is provided as an inert electrode. Conductive ions located within the dielectric region 2 may form a conductive path between the electrodes 3 so that the resistance of the resistive memory element is low. By applying a negative electrical field between the anode and the cathode of the resistive memory element 1, the conductive path is degenerated by forcing the conductive ions back to the anode. Thereby, the conductive path is dissolved such that the resistance of the resistive memory element increases. A resistive memory element is also called a non-symmetric electronic element due to its non-linear behavior. Resistive memory elements, e.g., on the basis of a chalcogenide material, are also called CBRAM memory elements or PMC memory elements, and other terms can be used as well. It is intended that the present invention relates to memory circuits using resistive memory elements which can be programmed by applying an electrical signal, in particular a programming voltage or current, a temperature and/or a magnetical field, and which change their resistance while the electrical signal, the temperature or the magnetical field is applied.

In FIG. 2, a cell current voltage diagram is depicted showing the hystereses of the resulting current in a resistive memory element when a programming voltage is applied. It is noted that the transitions between the high and the low resistance states occur when a voltage over a programming threshold voltage VTH1 and below an erasing threshold voltage VTH2 are respectively applied, i.e., a programming from a high to a low resistance state occurs if a voltage over the programming threshold voltage is applied and an erasing from a low to a high resistance state occurs if a voltage below the erasing threshold voltage is applied.

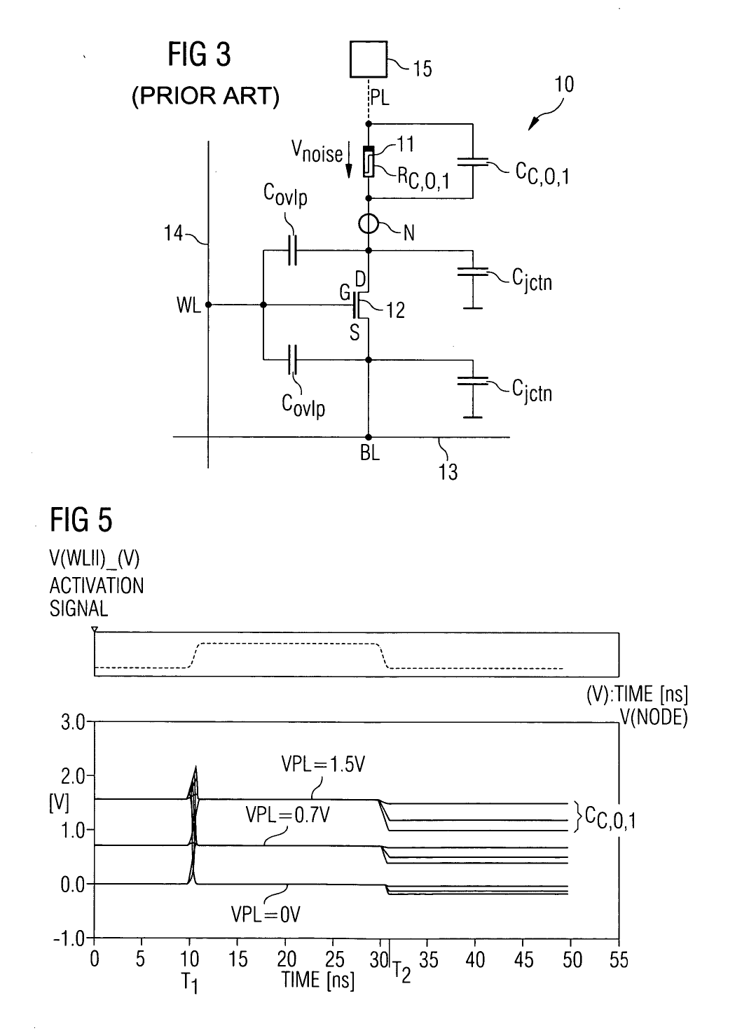

FIG. 3 shows a resistive memory cell 10 as typically provided in a CBRAM memory circuit. The resistive memory cell 10 comprises a resistive memory element 11 and a selection transistor 12 which are connected in series and coupled to a bit line 13 and a word line 14 to selectively address the resistive memory cell 10. The resistive memory element 11 is illustrated with a symbol of a box wherein the anode is indicated as a black filled end of the box. In detail, a first terminal, i.e., the anode, of the resistive memory element 11 is connected to a plate potential PL which is provided by a plate potential element 15. The plate potential is usually set as a constant potential in a range between a high and a low operating potential by which the memory circuit is operated. A second terminal, i.e., the cathode, of the resistive memory element 11 is connected to a first terminal of the selection transistor 12. A second terminal of the selection transistor 12 is coupled to the bit line 13. A gate terminal of the selection transistor 12 is coupled with the word line 14. The resistive memory cell 10 is addressed by applying an activation signal to the word line 14, a high level of which renders the selection transistor 12 conductive (i.e., the transistor is closed) such that the bit line 13 is coupled with the resistive memory element 11 through the selection transistor 12.

In the given example, a low level of the activation signal on the word line 14 results in the selection transistor 12 being non-conductive (i.e., the transistor is opened), and a high level of the activation signal results in the selection transistor 12 being rendered conductive (closed). Due to a capacitive coupling between the gate terminal and the node N, a level transition of the activation signal is capacitively-coupled to the node N. As shown in FIG. 3, the parasitic capacitances are provided between the node N and each of the plate potential element 15, the gate terminal and the substrate as well as between the second terminal of the selection transistor 12 and the gate terminal and the substrate. As can be further seen from the small signal diagram of FIG. 4, the resulting capacitance between the gate terminal and the first terminal of the selection transistor, i.e., the node N, causes the strength of the cross-coupling of the activation signal on the node to depend on the value of C_{OVLP}. As the second terminal of the selection transistor 12 is connected to the bit line 13, a charge which is induced from the word line 14 is equalized as the bit line 14 is usually connected with a respective voltage source such that the charges of the cross-talk signal are quickly removed. A cross-talk signal induced at a node between the second terminal of the resistive memory element 11 and the first terminal of the selection transistor 12 can be quickly removed if the selection transistor 12 is closed by the respective activation signal or if the resistive memory element 11 has a low resistance. In a case in which the resistive memory element 11 has a high resistance and the selection transistor 12 is opened due to the level transition of the activation signal on the word line 14, the node N floats and the level transition of the activation signal results in a remaining charge of the potential at the node N. If the activation signal goes from a high level to a low level, the potential of the node N drops, thereby increasing the voltage drop over the resistive memory element 11 which can come close or exceed the programming threshold voltage. This can lead to damages on the resistive memory element 11 and/or issues while operating the resistive memory cell.

This is illustrated in FIG. 5 wherein a signal-time-diagram shows the dependence of the node potential at the node N and the level transitions of the activation signal. At a time T₁, the level of the activation signal rises from a low level to a high level such that a positive charge is caused at the node N. As the high level of the activation signal closes the selection transistor 12, the charge induced at the node N is quickly removed via the bit line 13. At a time T₂, the activation signal passes from a high level to a low level, thereby inducing a negative charge at the node N. As the selection transistor 12 is opened with the low level of the activation signal, the charge cannot be removed via the bit line 13, and since the node N is floating, the additional negative charge lowers the potential of the node N. The diagram of FIG. 5 shows the behavior of the resistive memory cell 10 if the resistive memory element 11 is in its high resistance state.

The potential which is applied to the node N after the time T₂, i.e., at an opened selection transistor 12, may result in a voltage drop over the resistive memory element 11 which is higher than the programming threshold voltage which may change the resistance of the resistive memory element 11. Even if the charge and voltage drop is not sufficient to change the resistance state of the resistive memory element 11 to a low resistance state, the repeated application of such a parasitic voltage drop may result in that the resistance of the resistive memory element 11 drops after a plurality of addressing cycle wherein the resistive memory cell 10 is repeatedly read out. As may be seen from the signal time diagram of FIG. 5, the parasitic charge coupled in due to a level transition of the activation signal increases with a decreasing capacitance C_{C,0,1} of the resistive memory element 11 and with an increasing plate potential V_{PL}. That means that the higher the plate potential, the higher the voltage drop over the resistive memory element 11 due to the parasitic charge induced in by the word line.

One idea of the present invention is to change the potential of the node N before the selection transistor is opened such that the parasitic charge induced by the level transition of the activation signal is at least partially compensated. This is achieved, in the example of FIG. 3 wherein the anode is coupled with the plate potential element 15, by increasing the potential on the bit line 13 before the selection transistor 12 is opened so that the floating potential at the node N between the resistive memory element 11 and the selection transistor 12 has an increased potential, e.g., with regard to a normal read out potential for reading out the resistive memory cell 10, which is lowered as soon as the activation signal has a level transition from the high level to the low level such that the charge which is induced in the node N reduces the potential at the node N which has been increased before. The lowering of the potential at the node N results in an increase of the voltage drop between the anode and the cathode which is now smaller than in a case without the increasing of the node potential before opening of the selection transistor 12.

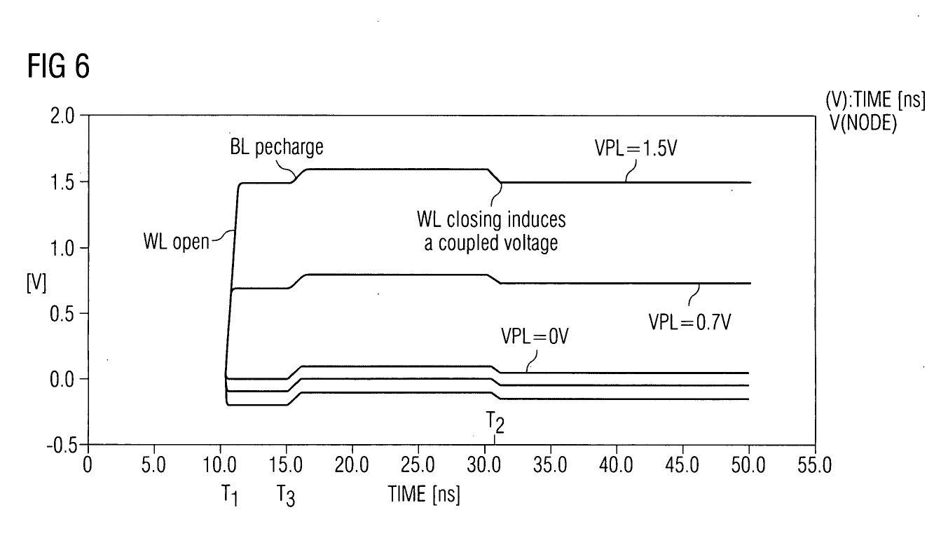

With regard to the signal time diagram of FIG. 6, the node potential is shown for different plate potentials VPL. At the time T₁, the selection transistor 12 is activated such that it is closed, wherein the bit line potential VBL, e.g., used for reading out the resistive memory cell is applied on the node N. Before the time T₁, the node N floats on an undetermined potential since it is provided that the resistive memory element 11 has a high resistance. The bit line potential is selected so that the voltage at the resistive memory element 11 is within a range between the erasing threshold voltage and the programming threshold voltage of the resistive memory element 11, such that neither an erasing nor a programming of the resistive memory element 11 occurs. The bit line potential may be used to read out the resistance state of the resistive memory element 11 to detect the information stored in the resistive memory cell 10. There are several ways of reading out the information from the resistive memory cell. The reading out can be performed by applying a voltage to the resistive memory element 11 and measuring the current flowing through the resistive memory element 11 or by applying a current and measuring the respective voltage drop over the resistive memory element. In the given case, the bit line 13 is set on a read out potential wherein the information stored within the resistive memory cell 10 is detected by measuring the current flowing on the bit line. After the state of the resistive memory element 11 has been detected, the potential on the bit line 13 is increased at a time T₃ before the selection transistor 12 is opened by means of a level transition of the activation signal from a high level to a low level. The increased bit line potential results in the potential at the node N also being provided with the increased bit line potential as the selection transistor 12 is conductive.

It is provided that both the increased potential at the node N and the potential resulting at the node N due to an overlayed parasitic charge induction resulting from the activation signal are within a potential range which is defined such that the voltage drop between the plate potential V_{PL} and the node potential is not higher than the programming threshold voltage. The difference between the bit line potential for reading out the compensation potential may be selected such that the voltage drop due to the deactivation of the selection transistor is at least partially compensated, fully compensated or overcompensated with regard to the above mentioned restrictions.

To implement this concept in a memory circuit, a plurality of designs is possible.

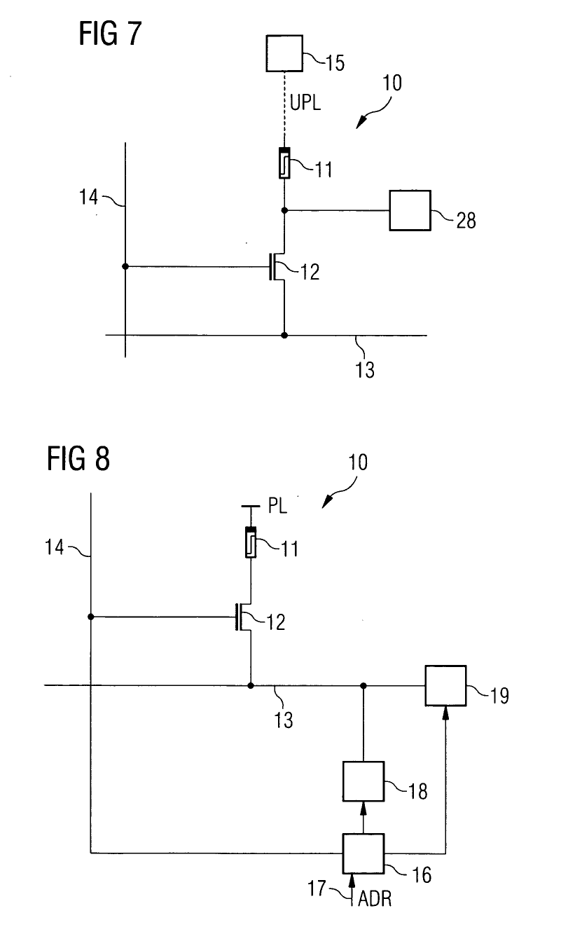

In FIG. 7, a portion of a memory circuit according to an embodiment of the present invention is schematically shown. The same reference signs indicate elements having the same or similar functionality. A memory circuit comprises a plurality of resistive memory cells 10 as indicated with regard to FIG. 3, only one of which is illustrated for clarity of illustration. The basic elements of the resistive memory cell 10 is designed similarly to the resistive memory cell shown in FIG. 3. Additionally,the node N between the resistive memory element 11 and the selection transistor 12 is coupled with a pre-charge circuit 28 which is operable to provide a compensation potential at the node N after closing of the selection transistor and prior to the opening of the selection transistor by means of the level transitions of the activation signal on the word line.

In FIG. 8, a portion of a memory circuit according to a further embodiment is schematically shown. The memory circuit comprises a plurality of resistive memory cells 10, only one of which is depicted for clarity of illustration. The memory circuit comprises a control circuit 16 which is coupled with the word lines of the memory circuit for applying an activation signal for selectively activating and deactivating a respective selection transistor 12 depending on an address ADR provided via an address line 17. The control circuit 16 is further coupled with the bit lines directly or, as in the given example, via a read voltage source 18 which is operable to apply a read out potential on each of the bit lines 13. The control circuit 16 is further connected to a pre-charge circuit 19 which is also coupled with the bit line 13 to apply the compensation potential to the bit line 13. The read out voltage source 18 and pre-charge circuit 19 can also be included in a single settable voltage source which is controlled by the control circuit 16.

In FIG. 8, the control circuit 16 controls the pre-charge circuit 19 depending on the resistance state of the resistive memory element 11 such that the compensation potential is only applied if the resistive memory element is in a high resistance state. The resistance state of the resistive memory element 11 can be determined by a read out procedure which has been carried out before or by a writing procedure in the addressed resistive memory cell which has been carried out prior thereto. If it is determined that the resistive memory element is in a low resistance state, the appliance of the compensation potential can be omitted as the charges through the node N can flow through the resistive memory element 11 to the plate potential element 15.

As described above, the control circuit 16 controls the bit line potential on the bit line 13 so that the read out potential is applied for reading out the selected resistive memory cell when the selection transistor 12 is closed. Before opening the selection transistor 12 as it is controlled by the control circuit 16, the pre-charge circuit 19 is activated to supply the compensation potential to the bit line 13 before the activation signal transitions to a low level which is applied by the control circuit 16. The application of the compensation potential may depend on the resistance state of the resistive memory element, as explained before.

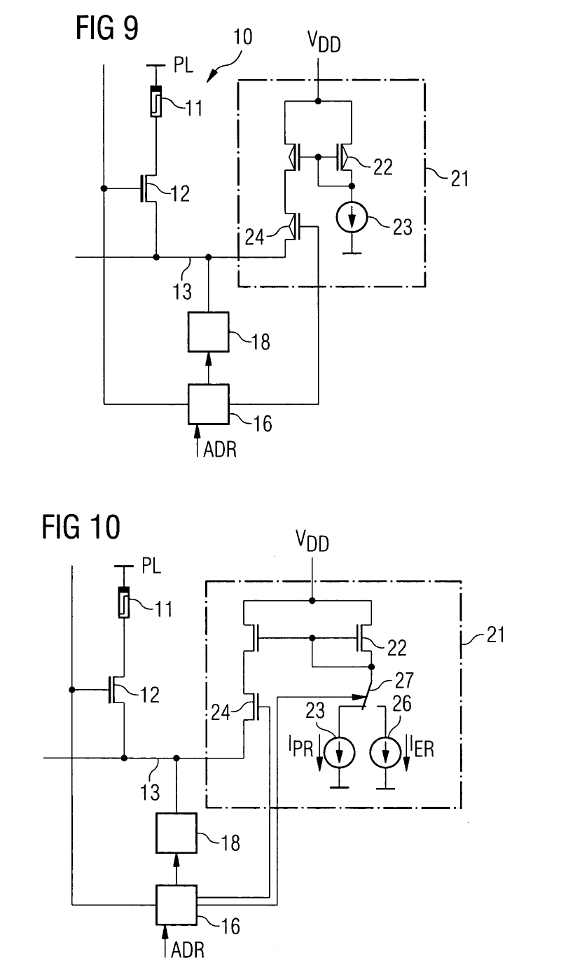

In FIG. 9, another embodiment of the present invention is shown. The embodiment of FIG. 9 substantially differs from the embodiment of FIG. 8 in that the pre-charge circuit 19 of FIG. 8 is replaced by a further pre-charge circuit 21 which includes a current source for applying a compensation current via the bit line 13 to the resistive memory cell 10. The pre-charge circuit 21 comprises a current mirror 22 and a reference pre-charge current source 23, wherein the current mirror 22 mirrors the current defined by the reference pre-charge current source 23 via a pre-charge transistor 24 to the bit line 13. The pre-charge transistor 24 is connected between the current mirror 22 and the bit line 13 and is controlled by its gate terminal by means of the control circuit 16. The compensation current I_{comp} is selected such that in case that the resistive memory element 11 of the addressed resistive memory cell 10 is in a high resistance state, the bit line, i.e., its capacitance, is charged with the pre-charge current supplied by the further pre-charge circuit 21 during a time which is predefined by the control circuit 16. The compensation current I_{comp} and the time during which the compensation current is applied to the bit line before opening the selection transistor 12 are selected in such a way that the node N between the resistive memory element 11 and the selection transistor 12 is loaded with a resulting compensation potential. The time during which the compensation current is applied to the bit line 13 is limited by the opening of the selection transistor 12 which cuts the flow of the compensation current through the selection transistor 12 to the node N. In a case in which the resistive memory element 11 of the addressed resistive memory cell 10 is in a low resistance state, the compensation current I_{comp} supplied by the pre-charge circuit 21 flows via the bit line 13 through the closed selection transistor 12 and through the resistive memory element 11, thereby resulting in a voltage drop over the resistive memory element 11 which is much smaller than the voltage drop caused by the charging of the node N before opening the selection transistor 12. Thus, it is not necessary for the control circuit 16 to control the pre-charge circuit depending on the resistance state of the resistive memory element 11, since the appliance of the compensation current for a predetermined time period automatically pre-charges the node N in a predetermined manner or not.

The control circuit 16 may control the pre-charge circuit 19 of FIG. 8 depending on an information stored in the resistive memory cell 10. The stored information can be detected by a foregoing read-out or write-in cycle on the addressed resistive memory cell 10.

In FIG. 10, another embodiment of the present invention is shown. The embodiment of FIG. 10, which is similar to the embodiment of FIG. 9 wherein the pre-charge circuit 21 comprises the reference pre-charge current source 23, further includes an erasing current source 26 which can be selectively coupled to the current mirror 22 by means of a switch 27 which is controlled by the control circuit 16. As the direction of the current flow via the bit line into the resistive memory cell 10 is the same for the precharging and for erasing the resistive memory cell, the pre-charge circuit 21 can also be used for supplying an erasing current I_{ER}. The erasing current I_{ER} is selected in such a way that, when applied to the resistive memory cell 10, a voltage drop over the resistive memory element 11 is applied which is lower than the erasing threshold voltage V_{TH2}.

In the above described embodiments, the resistive memory element 11 is arranged such that the anode is connected with the plate potential V_{PL} and the cathode is connected with the node N. In this case, a negative charge induced by a level transition of the activation signal from high to low has to be avoided since the negative charge increases the voltage drop over the resistive memory element in the direction of the programming threshold voltage, and a change of the resistance state of the resistive memory element to a low resistance state can occur as a result. There is no negative effect if the charge which is induced at the node N is positive. While opening and closing the selection transistor, charges with different signs are induced. The resistive memory element has to be arranged in such a way that, while activating the selection transistor, an erasing voltage is applied to the resistive memory element and while deactivating the selection transistor, the programming voltage is induced which has to be reduced or canceled by applying the compensation potential.

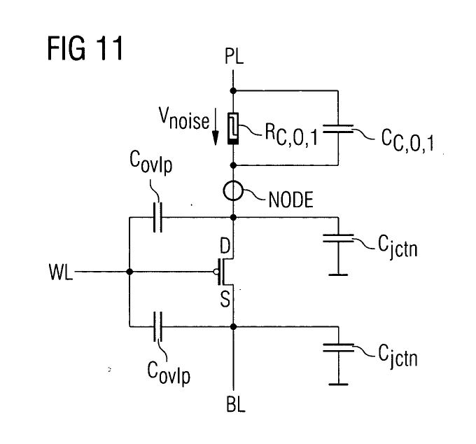

Taking into account this behavior, in a resistive memory cell having a resistive memory element arranged in an inverse manner, i.e., a cathode coupled with the plate potential and the anode coupled with the node as shown in FIG. 11, instead of the selection transistor of a n-type, a selection transistor of a p-type has to be implemented which is controlled by an inverse logic (low active) with regard to the activation signal. This means that the selection transistor of the p-type is activated by a low level and deactivated by a high level of the activation signal. Thereby, an activation of the selection transistor results in a level transition of the activation signal from a high level to a low level which causes a drop of the potential at the node N, i.e., in a direction of the erasing voltage with respect to the resistive memory element. A deactivation of the selection transistor is performed by a level transition from a low level to a high level which results in an increase of the voltage over the resistive memory element 11 and which has to be compensated by a compensation voltage which is lower than the bit line potential normally used for reading out the resistive memory cell. The measures as explained above with regard to the embodiments of FIGS. 6 to 10 can be applied to produce the compensation potential in a respective manner, e.g., by using an adequate logic.

While the foregoing is directed to embodiments of the present invention, other and further embodiments of the invention may be devised without departing from the basic scope thereof, and the scope thereof is determined by the claims that follow.

What is claimed is:

1. A memory circuit, comprising:
a resistive memory cell having a selection transistor and a resistive memory element connected in series, wherein the resistive memory element is coupled with a plate potential;
a control circuit to control the selection transistor by an activation signal; and
a pre-charge circuit coupled to a node between the selection transistor and the resistive memory element and to apply a compensation potential to the node;
wherein the control circuit controls the pre-charge circuit to apply the compensation potential to the node prior to a level transition of the activation signal.

2. The memory circuit of claim 1, wherein the resistive memory element acquires a high resistance state by applying an erasing voltage which is lower than an erasing threshold voltage and acquires a low resistance state by applying a programming voltage which is higher than a programming threshold voltage, wherein the programming voltage and the erasing voltage have inverse polarities.

3. The memory circuit of claim 2, wherein the control circuit activates the pre-charge circuit only when the resistive memory element is in the high resistance state.

4. The memory circuit of claim 3, wherein the compensation potential is selected to compensate, at least partially, a coupling signal induced by the level transition of the activation signal at the node, and wherein the compensation potential is further selected such that a resulting voltage over the resistive memory element is below the programming threshold voltage.

5. The memory circuit of claim 1, wherein the control circuit controls the pre-charge circuit to apply the compensation voltage after a closing of the selection transistor.

6. A memory circuit, comprising:
a resistive memory cell having a selection transistor and a resistive memory element connected in series, wherein a plate potential is connected with a first terminal of the resistive memory cell;
a bit line coupled with a second terminal of the resistive memory cell;
a control circuit connected to control the selection transistor; and
a pre-charge circuit connected to supply a compensation potential;
wherein the control circuit controls the pre-charge circuit to apply the compensation potential on the bit line prior to an opening of the selection transistor.

7. The memory circuit of claim 6, wherein the control circuit controls the pre-charge circuit to apply the compensation voltage after a closing of the selection transistor.

8. The memory circuit of claim 6, wherein the resistive memory element acquires a high resistance state by applying an erasing voltage which is lower than an erasing threshold voltage and acquires a low resistance state by applying a programming voltage which is higher than a programming threshold voltage.

9. The memory circuit of claim 8, wherein the control circuit applies an activation signal on a word line to selectively open and close the selection transistor, wherein the compensation potential is selected to compensate, at least partially, a coupling signal induced by a level transition of the activation signal at a node between the selection transistor and the resistive memory element.

10. The memory circuit of claim 9, wherein the compensation potential is further selected such that a resulting voltage over the resistive memory element is within a range between the programming threshold voltage and the erasing threshold voltage.

11. The memory circuit of claim 6, wherein a memory access circuit is provided for at least one of writing a data to and reading a data from the resistive memory cell, and wherein the control circuit further controls the pre-charge circuit to apply the compensation potential depending on the resistance state of the resistive memory element related to the data written to and read from the resistive memory cell.

12. A memory circuit, comprising:
a resistive memory cell having a selection transistor and a resistive memory element connected in series, wherein a plate potential is connected with a first terminal of the resistive memory cell;
a bit line coupled with a second terminal of the resistive memory cell;
a control circuit which controls the selection transistor; and
a pre-charge circuit operable to supply a compensation current via the bit line to the resistive memory cell;
wherein the control circuit further controls the pre-charge circuit to apply the compensation current via the bit line through the resistive memory cell prior to an opening the selection transistor.

13. The memory circuit of claim 12, wherein the control circuit controls the pre-charge circuit to apply the compensation current after a closing of the selection transistor.

14. The memory circuit of claim 12, wherein the resistive memory element acquires a high resistance state by applying an erasing voltage which is lower than a erasing threshold voltage and to acquire a low resistance state by applying a programming voltage which is higher than a programming threshold voltage.

15. The memory circuit of claim 14, wherein the compensation current is applied on the resistive memory cell for a predetermined time and results in a compensation potential applied on a node between the selection transistor and the resistive memory element when the resistive memory element is in the high resistance state, and results in a further potential applied on the node when the resistive memory element is in the low resistance state, wherein the further potential is selected such that a resulting voltage applied on the resistive memory element is higher than the erasing threshold voltage.

16. The memory circuit of claim 15, wherein the control circuit controls the pre-charge circuit to apply the compensation current after a closing of the selection transistor.

17. A memory circuit, comprising:
a resistive memory cell having a selection transistor and a resistive memory element connected in series, wherein a plate potential is connected with a first terminal of the resistive memory cell;
a bit line coupled with a second terminal of the resistive memory cell;
a control circuit connected to control the selection transistor; and
a pre-charge/writing circuit connected to selectively supply one of a compensation current and a writing current via the bit line to the resistive memory cell;
wherein the control circuit controls the pre-charge/writing circuit to apply one of the compensation current via the bit line through the resistive memory cell prior to an opening of the selection transistor and the writing current via the bit line through the resistive memory cell to bring the resistive memory element of the resistive memory cell into a defined resistance state.

18. The memory circuit of claim 17, wherein the resistive memory element acquires a high resistance state by applying an erasing voltage which is lower than a erasing threshold voltage and to acquire a low resistance state by applying a programming voltage which is higher than a programming threshold voltage.

19. The memory circuit of claim 18, wherein the compensation current is applied on the resistive memory element for a predetermined time and results in a compensation potential applied on a node between the selection transistor and the resistive memory element when the resistive memory element is in the high resistance state and results in a further potential applied on the node when the resistive memory element is in the low resistance state, wherein the further potential is selected such that a voltage applied on the resistive memory element is higher than the erasing threshold voltage.

20. The memory circuit of claim 18, wherein the writing current is applied to the resistive memory element and results in a potential applied on a node between the selection transistor and the resistive memory element which brings the resistive memory element in one of the high resistance state and the low resistance state.

21. A method for operating a memory circuit comprising a resistive memory cell having a selection transistor and a resistive memory element connected in series, the method comprising:
controlling the selection transistor by means of an activation signal; and
applying a compensation potential on a node between the selection transistor and the resistive memory element prior to a level transition of the activation signal.

22. The method of claim 21, wherein the compensation potential is applied only when the resistive memory element is in its high resistance state.

23. The method of claim 22, wherein the compensation potential is selected to compensate, at least partially, a coupling signal induced by the level transition of the activation signal at the node, wherein the compensation potential is further selected such that a resulting voltage over the resistive memory element is below the programming threshold voltage so that no programming of the resistive memory element occurs.

24. A method for operating a resistive memory cell comprising a selection transistor and a resistive memory element connected in series, wherein the resistive memory cell is coupled with a bit line, the method comprising:
controlling the selection transistor by means of an activation signal; and
applying a compensation potential on the bit line prior to an application of the activation signal which opens the selection transistor.

25. The method of claim 24, wherein the activation signal is applied on a word line to selectively open and close the selection transistor, wherein the compensation potential is selected to compensate, at least partially, a coupling signal induced by a level transition of the activation signal at a node between the selection transistor and the resistive memory element.

26. The method of claim 25, wherein the compensation potential is further selected such that a resulting voltage applied on the resistive memory element is below a programming threshold voltage in which no programming of the resistive memory element occurs.

27. The method of claim 25, further comprising:
at least one of writing data to and reading data from the resistive memory cell; and
applying the compensation potential depending on the resistance state of the resistive memory element related to the data written to and read from the resistive memory cell, respectively.

28. A method for operating a resistive memory cell comprising a selection transistor and a resistive memory element connected in series, the method comprising:
controlling the selection transistor by means of an activation signal; and
applying a compensation current via a bit line connected to the resistive memory cell prior to an opening the selection transistor, wherein the compensation current is applied for a predetermined time, wherein the resulting voltage applied on the resistive memory element is below a programming threshold voltage so that no programming of the resistive memory element occurs.

29. The method of claim 28, wherein the compensation current is applied and results in a compensation potential applied on a node between the selection transistor and the resistive memory element when the resistive memory element is in the high resistance state, and results in a further potential applied on the node when the resistive memory element is in the low resistance state, wherein the further potential is selected such that a resulting voltage applied on the resistive memory element is higher than the erasing threshold voltage over which no erasing of the resistive memory element occurs.
